(19) United States
(12) Patent Application Publication
(10) Pub. No.: US 2004/0115934 A1
(43) Pub. Date: Jun. 17, 2004

(54) Method of improving contact resistance

(76) Inventors: Jerry Broz, Longmont, CO (US); Cheryl Hartfield, McKinney, TX (US); Elizabeth R. Kramer, Dallas, TX (US); Randy Pak, Plano, TX (US); Hansley Regan Rampersad, Dallas, TX (US); Phillip R. Coffman, Rowlett, TX (US); Sunny K. Lee, Garland, TX (US)

Correspondence Address: TEXAS INSTRUMENTS INCORPORATED, P O BOX 655474, M/S 3999, DALLAS, TX, 75265

(21) Appl. No.: 10/319,213

(22) Filed: Dec. 13, 2002

(51) Int. Cl. H01L 21/302; H01L 21/461

(52) U.S. Cl. 438/689; 438/690

(57) ABSTRACT

A method for improving the electrical resistance of contacts on an integrated circuit. The method includes the steps of first exposing the contacts to a solvent, thereby removing organic contaminants; and then exposing the contacts to ion bombardment, thereby removing inorganic contaminants. The step of exposing the contacts to ion bombardment can remove a portion of the contact. The method may also include a step of oxidizing the pad to produce an oxide layer of a predetermined thickness. The ion bombardment can be carried out in a parallel plate etch tool or by using the RIE tool used to carry out a previous etch step. Another embodiment of the invention is a method of improving the resistance of contacts on an integrated circuit including the steps of: exposing the contacts to ion bombardment in the presence of a fluorine and oxygen plasma, thereby removing inorganic contaminants; and exposing the contacts to a solvent, thereby removing organic contaminants. The step of exposing the contacts to a solvent can remove a portion of the contact. The method can also include the step of oxidizing the pad to produce an oxide layer of a predetermined thickness. The ion bombardment can be carried out in an inductively coupled plasma etch tool, an RF/microwave plasma etch tool, or a tool combining these capabilities. The solvent in these embodiments is selected from the group consisting of n-methyl pyrrolidone, isopropyl alcohol, methanol, glycol, or a dimethylacetamide-based formulation, and is preferably a formulation comprising n-methylethanolamide, dimethylacetamide, 8-hydroxyquinoline, and water.

### BACKGROUND OF THE INVENTION

This invention is in the field of integrated circuits, and more particularly in the field of methods of improving contact resistance on integrated circuits.

In the testing and operation of integrated circuits, contact resistance is an important factor in determining the performance characteristics of a device. The contact resistance between a probe tip and the test pad on the integrated circuit can determine whether the device under test passes a parametric test or fails it. A thousand or more probe contacts may be necessary to test all of the integrated circuits on a particular semiconductor wafer, and to make efficient use of costly test equipment, it is highly desirable that the probe operation be continuous and uninterrupted. Unfortunately, due to a build-up of oxidized metal residues and other contaminants after repeated touchdowns on test pads fabricated using conventional processes, it is a usual practice to stop the probe test operation periodically to clean the probe tips. Since the test tool typically costs millions of dollars, ceasing operations for this periodic cleaning of the probe tips is highly undesirable. In addition, the cost of consumables such as probe cards and conditioning pads also increases with the number of cleaning cycles between probe touchdowns.

In addition, modern contact structures on integrated circuits, including both wire bonded and flip-chip types, typically comprise several layers of metal applied at various times during the fabrication and packaging of the integrated circuit. The oxidized metal residues and other contaminants that have an adverse effect on the testing of an integrated circuit can also affect the contact resistance and consequently the performance of the integrated circuit. Bonds or bumps on a contaminated pad necessarily have a higher series resistance than would similar contacts made on pristine pads. Therefore, there is a need in the industry for techniques to both improve the testability and performance of integrated circuits.

### BRIEF SUMMARY OF THE INVENTION

In one embodiment of the invention, a method is disclosed for improving the electrical resistance of contacts on an integrated circuit. The method includes the steps of first exposing the contacts to a solvent, thereby removing organic contaminants; and then exposing the contacts to ion bombardment, thereby removing inorganic contaminants. The step of exposing the contacts to ion bombardment can remove a portion of the contact. The solvent is selected from the group consisting of n-methyl pyrrolidone, isopropyl alcohol, methanol, glycol, or a dimethylacetamide-based formulation, and is preferably n-methyl pyrrolidone. The ion bombardment can be carried out in a parallel plate etch tool or by using the RIE tool used to carry out a previous etch step.

Another embodiment of the invention is a method of improving the resistance of contacts on an integrated circuit including the steps of: exposing the contacts to ion bombardment in the presence of a fluorine and oxygen plasma, thereby removing inorganic contaminants; and exposing the contacts to a solvent, thereby removing organic contaminants. The step of exposing the contacts to a solvent can remove a portion of the contact. The method can also include the step of oxidizing the pad to produce an oxide layer of a predetermined thickness. The solvent is selected from the group consisting of n-methyl pyrrolidone, isopropyl alcohol, methanol, glycol, or a dimethylacetamide-based formulation, and is preferably dimethylacetamide, n-methylethanolamine, 8-hydroxyquinoline, and water. The ion bombardment can be carried out in an inductively coupled plasma etch tool, an RF/microwave plasma etch tool, or a tool combining these capabilities.

Still another embodiment of the invention is a method of forming contacts on an integrated circuit, including the steps of: depositing a protective overcoat over the integrated circuit, including over a plurality of bond pads on the integrated circuit; removing the protective overcoat from the bond pads in a reactive ion etching process carried out in a reactive ion etching tool; exposing the bond pads to ion bombardment, wherein the ion bombardment is carried out in the reactive ion etching tool; and attaching a coupling member to the pad after the step of exposing the pad to ion bombardment. The method can also include, following the step of exposing the bond pads to ion bombardment in a reactive ion etching tool, a step of exposing the bond pads to ion bombardment in the presence of a fluorine and oxygen plasma. Further, the method can include the step of exposing the bond pads to a solvent. The solvent is selected from the group consisting of n-methyl pyrrolidone, isopropyl alcohol, methanol, glycol, or a dimethylacetamide-based formulation. The ion bombardment in the presence of a fluorine and oxygen plasma can be carried out in an inductively coupled plasma etch tool, an RF/microwave plasma etch tool, or a tool combining these capabilities.

An advantage of the invention is that it provides a method for the removal of contaminants and residues that form on bond pads or contacts during processing of an integrated circuit. The removal of these contaminants and residues greatly facilitates probing of the bond pads during testing, and in subsequent steps, it allows for a lower contact resistance between a coupling member such as a wire bond, a redistribution trace, or a solder bump and the bond pad.

### BRIEF DESCRIPTION OF THE SEVERAL VIEWS OF THE DRAWINGS

The invention can be more fully understood by reading the following detailed description of preferred embodiments of the invention with reference to the accompanying drawings. One skilled in the art will appreciate that the drawings are not to scale; in particular, the vertical dimension is typically exaggerated to better show the details of the embodiments.

FIGS. 1a to 1c are cross-sectional diagrams of the upper portion of an integrated circuit at various steps during the formation of an opening in a protective overcoat layer over a bond pad.

FIG. 1d is an illustration of a test probe contacting a bond pad.

FIG. 1e shows a wire bond on a bond pad.

FIG. 1f shows a bond pad attached to a redistribution trace as is used in Bond Over Active Circuit technology.

FIGS. 2a to 2d are cross-sectional diagrams of the upper portion of a flip-chip integrated circuit at various steps during the formation of an opening in PBO and protective overcoat layers over a bond pad.

FIGS. 3a to 3c are cross-sectional diagrams of the upper portion of a flip-chip integrated circuit at various steps during the formation of an opening in PIQ and protective overcoat layers over a bond pad.

FIG. 4a and 4b are cross-sectional diagrams at two stages in the formation of a solder bump on a bond pad.

### DETAILED DESCRIPTION OF THE INVENTION

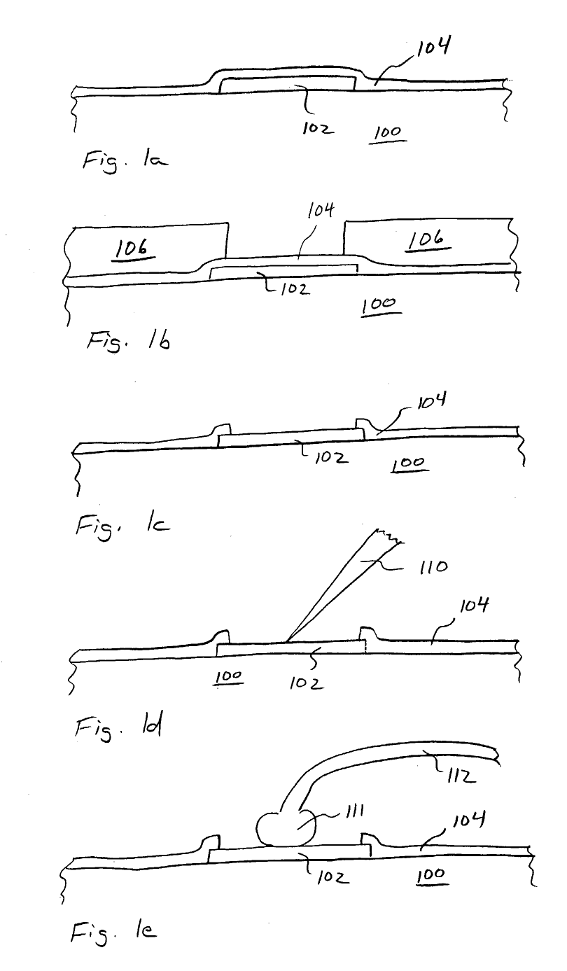

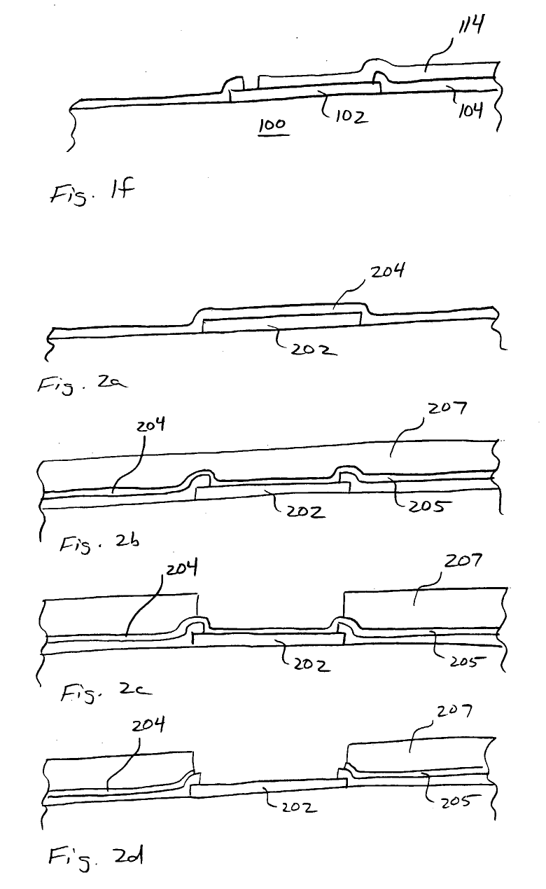

In a preferred embodiment of the invention, metal pads on an integrated circuit are conditioned to reduce the presence of metal oxides or other contaminants on the pad surface. In FIG. 1a, a metal pad 102 (e.g. aluminum, aluminum with silicon, or aluminum with copper, copper) is formed on a dielectric layer 100 (e.g. silicon oxide, a glass, or low-k dielectric) at the surface of a semiconductor wafer. A protective overcoat 104 is deposited over the pad 102 and the surface of the dielectric layer 100. The protective overcoat 104 can be a silicon oxynitride layer, alternating layers of oxide or glass with nitride, or similar materials. The protective overcoat protects the integrated circuit from mechanical damage and the ingress of moisture. In FIG. 1b, photoresist 106 has been deposited, exposed, and developed to leave an opening over the pad 102. The protective overcoat layer 104 is then etched with a fluorine-containing plasma (e.g. a combination of C₂F₆, SF₆, C₃F₈, CHF₃, CF₄, or C₄F₈ with O₂, H₂ or NF₃), for example, to expose the surface of pad 102. FIG. 1c shows the structure at this point in the process and after the photoresist 106 has been removed using an oxygen plasma (i.e. an ash step). In the prior art, the integrated circuit is essentially in its finished state at this point. However, the pad surface is covered with metal fluorides, metal oxides, organic residues, and contaminants resulting from the protective overcoat etch, as well as from the photoresist ash. The residues and contaminants can have an adverse effect on the contact resistance of the pad. The wafer may be sintered and then baked. FIG. 1d illustrates the contact between a test probe 110 and the pad 102, while FIG. 1e shows a ball bond 111 of a gold wire 112 to the pad 102, and FIG. 1f shows a redistribution trace 114 as is used in Bond Over Active Circuitry (BOAC) metallization schemes. In all of these applications, removal of pad contaminants is an important part of achieving lower contact resistance.

The removal of pad contaminants is important for forming low contact resistance bumps on flip-chip integrated circuits as well. In FIG. 2a, pad 202 is covered with a protective overcoat layer 204 as in FIG. 1a. Following patterning and etching of the protective overcoat (as in FIG. 1c), a pad protective layer 205 of nitride and TEOS oxide about 500 Angstroms in thickness is formed over the wafer. A polybenzoxazole (PBO) layer 207 is formed over the pad protective layer 205. The PBO layer helps absorb and distribute stresses that can cause the failure of subsequently-applied solder balls, while the pad protective layer 205 protects the pad 202 from moisture and other contaminants during the patterning and curing of the PBO layer 207. The PBO layer 207 typically comprises polyimide, but can be made of a similar stress-absorbing material such as benzocyclobutene, for example. As shown in FIG. 2b, the PBO layer 207 covers the pad protective layer 205. The PBO layer is preferably photosensitive and can be used in a manner similar to photoresist. That is, the layer can be selectively exposed and developed to leave an opening over pad 202, as shown in FIG. 2c. This step leaves the pad protective layer 205 over pad 202 exposed, and in a subsequent step, this exposed portion of the pad protective layer 205 can be removed with a fluorine-containing plasma (e.g. a combination of C₂F₆, SF₆, C₃F₈, CHF₃, CF₄, or C₄F₈ with O₂, H₂ or NF₃) in a reactive ion etching chamber, for example. The resulting structure is shown in FIG. 2d. In the prior art, a solder bump is applied to the pad at this point in the process. However, as in the wirebonded integrated circuit described above with reference to FIGS. 1a to 1c, the pad surface is covered with metal fluorides, metal oxides, organic residues, and contaminants resulting from the removal of the PBO layer as well as from the removal of the pad protective layer. This undesirable residue on the pad can have an adverse effect on the contact resistance of the pad and is preferably removed prior to continued processing of the wafer.

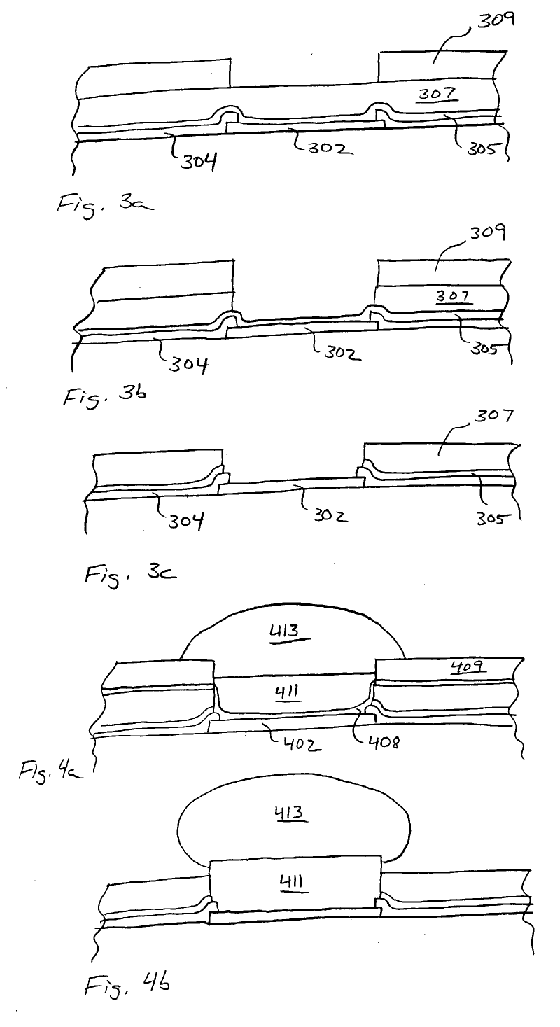

As an alternative to the photosensitive polyimide layer 207 shown in FIGS. 2a to 2d, a polyisoquinazorindione (PIQ) layer can be used as shown in FIGS. 3a to 3c. In FIG. 3a, pad 302 has been covered with protective overcoat 304, which has in turn been patterned to expose pad 302. Pad protective layer 305 has been deposited on the wafer to cover the protective overcoat 304 as well as the pad 302. A layer of PIQ 307 has then been deposited to cover the pad protective layer 305. Photoresist is then spun on over the PIQ layer, exposed, and then developed to form the structure shown in FIG. 3a. In FIG. 3b, the PIQ layer 307 is etched from over pad 302 using, for example, an aqueous alkaline wet etchant such as TMAH (tetramethylammonium hydroxide), and in FIG. 3c the pad protective layer 305 is etched to clear the pad. Photoresist 309 is then removed in an oxygen plasma (i.e. an ash step). As in the case in which the stress-absorbing layer is polyimide, a large amount of both organic and inorganic residue is left on the bond pad from these procedures. No matter whether the stress-absorbing layer is polyimide or another polymer, after implementing the pad cleaning procedures described hereinbelow, a layer of under-bump metal 408 is applied to the surface of the wafer (refer to FIG. 4a), followed by a photoresist layer 409, which is patterned to expose the bond pad 402. Copper 411 and solder 413 are then plated onto the pad. Upon removal of the photoresist 409, removal of the exposed under-bump metal 408, and reflowing the solder 413, the bumped electrode appears as shown in FIG. 4b.

In one preferred embodiment of the invention, the bond pads are conditioned to remove the inorganic and organic contaminants from the pad surface by exposing the wafer upon which the integrated circuit and bond pads are fabricated to a solvent-based cleaning step, followed by a sputter etch. The solvent-based cleaning step serves to remove organic contaminants and preferably includes immersing the wafer in n-methyl pyrrolidone at a temperature of about 60° C., followed by an isopropanol wash, and deionized water spin rinse dry. Alternatively, the solvent can be agitated isopropyl alcohol, methanol, or glycol, for example, or a similar chemical effective at removing organic residues. The solvent can also be used in conjunction with ultrasonic energy, and may be either heated or unheated. In addition to immersion, the solvent can be applied to the wafer in a spray or as a chemical vapor.

Following the solvent-based cleaning step, the wafer surface is subjected to an ion bombardment in a glow discharge plasma, for example, primarily to remove inorganic contaminants (it should be noted that the capability of ion bombardment in a glow discharge plasma to remove inorganic versus organic materials can be adjusted by decreasing oxygen content in the plasma to remove inorganic materials and increasing oxygen content to remove organic materials). It is advantageous in this embodiment that the ion bombardment follows the solvent-based cleaning step since thick organic contaminants can absorb the energy of impending ions and render them relatively ineffective in removing inorganic residue. Performed after the solvent-based cleaning step, the ion bombardment or sputtering causes a physical removal of the top surface layer of the pad, thereby exposing a fresh metal surface free of contaminants. A controlled re-oxidation of the pad surface then follows to form a dense, protective layer that is thin enough to be probed through, yet thick and dense enough to prevent unwanted further oxidation that can have an adverse effect on contact resistance. The oxide is formed when a fresh, clean aluminum surface, stripped of most of the oxide and other contaminants, is re-oxided in air.

The ion bombardment or sputter etch can be carried out in a variety of plasma chambers. One such chamber is the hard etch chamber of a pre-clean sputter etch tool. Such a chamber can have a parallel plate arrangement and a 13.56 MHz capacitance-coupled plasma, for example. The gap between electrodes in this chamber is preferably approximately 2.5 cm and the process is preferably carried out at approximately 10 to 12 mTorr using flowing Argon at a rate of about 100 sccm, with a Helium clamp set at about 6 to 8 Torr. A self-forming voltage bias of 850 to 1000 Volts is preferably used for between about 90 seconds and 240 seconds. The temperature used for the procedure is in the range of about 100° C. to 300° C., and is preferably about 200° C. This process removes an equivalent thickness of about 150 Angstroms to 500 Angstroms of thermal silicon oxide and removes about 50 Angstroms to 275 Angstroms of pad metal (e.g. aluminum) as well. If the pad metal is copper, more of the metal would be removed in this process. Another such chamber includes an inductively coupled plasma with an RF bias applied to the substrate.

In another preferred embodiment of the invention, in which a pad protective layer, such as layer 205 in FIG. 2c or layer 305 in FIG. 3b, covers the pad, a reactive ion etching (RIE) process using a fluorine-based reactant is used to remove the pad protective layer from over the pad. Before removing the wafer from the etch chamber of the RIE tool, the wafer is subjected to ion bombardment or sputtering as described above. That is, the sputtering step in the two step process of cleaning the pad of organic and inorganic residue can be incorporated into the step in which the pad protective layer is removed, rather than loading the wafer into a separate tool specifically for sputtering. The RIE tool has a gap between the electrodes of approximately 1.4 cm and the process is carried out at approximately 20 to 100 mTorr using flowing Argon at a rate of about 50 to 200 sccm, with a Helium clamp set at about 8 Torr, and RF power level at about 850 to 100 Watts. The temperature used for the procedure is in the range from about −20° C. to about 25° C. The process time used in this embodiment is in the range equivalent to the time needed to remove thermal silicon oxide having a thickness of from about 150 Angstroms to about 500 Angstroms. An optional solvent-based organic clean-up step can either precede or follow the RIE sputtering step.

In another preferred embodiment, a C₂F₆/oxygen ash may be used to condition the bond pad after the pad protective layer is etched, as opposed to the hard sputter steps described in the embodiments above. Alternatives to C₂F₆/oxygen include a combination of C₂F₆, SF₆, C₃F₈, CHF₃, CF₄, or C₄F₈ with O₂, H₂ or NF₃. The tool in which this step takes place preferably includes a microwave/RF plasma, an inductively coupled plasma, or a combination thereof. The tool can be made to remove material at a slower rate than does the parallel plate tools described above. This type of material removal is known as “soft etching.” The pad conditioning step preferably takes place under a pressure of about 1.1 Torr, at an RF power of about 950 Watts, and a temperature of about 250° C. The C₂F₆ flow is about 6 sccm and the O₂ flow is about 3000 sccm. This fluorine/oxygen soft etching process step removes a negligible amount of aluminum, and approximately 100 Angstroms of thermal silicon oxide equivalent. The step can be followed by a step in which the wafer is immersed in, sprayed with, or exposed to the vapor of, an organic stripper solvent, such as a formulation containing 91.74% dimethylacetamide, 5.82% n-methylethanolamine, 2.34% 8-hydroxyquinoline, and <1% water (available commercially as Ashland ACT™ CMI). This solvent step removes about 85 Angstroms to 100 Angstroms of the pad material (e.g. aluminum). The surface layer that forms after reoxidation has low mechanical hardness and low surface roughness so that reliable probing to the pad is possible. The formation of coupling members such as wire bonds and bumps is also facilitated since Applicants have shown that the surface layer that forms on the pad after reoxidation possesses these desirable qualities for at least about 60 days. Hence, the wafer can be safely stored in a controlled environment for this length of time before a wire bonding step (FIG. 1e), application of a redistribution trace (FIG. 1f), or deposition of an underbump metal layer and solder ball (FIG. 4a) is carried out to complete the wafer.

Note that although these various procedures have been described as separate embodiments, advantages of the invention may also be obtained from combining aspects of the embodiments. For example, the bond pad cleaning or conditioning process can include not only a solvent-based step and a hard sputter step, but a soft etch step or a fluorine/oxygen plasma-based step as well. Or, the process can include the hard sputter following removal of the pad protective layer, in addition to the fluorine/oxygen plasma process plus the solvent-based cleaning step. Or, as described hereinabove, the process can include only a solvent-based step and a hard sputter step, a soft-etch step, or a fluorine/oxygen plasma-based step along with a solvent-based step. Such combinations and modifications are within the scope of Applicant's invention.

While the present invention has been described according to its preferred embodiments, it is of course contemplated that modifications of, and alternatives to, these embodiments, such modifications and alternatives obtaining the advantages and benefits of this invention, will be apparent to those of ordinary skill in the art having reference to this specification and its drawings. It is contemplated that such modifications and alternatives are within the scope of this invention as claimed hereinbelow.

We claim:

1. A method for improving the electrical resistance of contacts on an integrated circuit, comprising the steps of:
first exposing said contacts to a solvent, thereby removing organic contaminants; and
then exposing said contacts to ion bombardment, thereby removing inorganic contaminants.

2. The method of claim 1, wherein said step of exposing said contacts to ion bombardment removes a portion of the contact.

3. The method of claim 1, further comprising the step of oxidizing said pad to produce an oxide layer of a predetermined thickness after said steps of exposing said contacts to a solvent and exposing said contacts to ion bombardment.

4. The method of claim 1, wherein said step of exposing said contacts to a solvent comprises exposing said contacts to a solvent selected from the group consisting of n-methyl pyrrolidone, isopropyl alcohol, methanol, glycol, or a dimethylacetamide-based formulation.

5. The method of claim 1, wherein said step of exposing said contacts to a solvent comprises exposing said contacts to n-methyl pyrrolidone.

6. The method of claim 1, wherein said step of exposing said contacts to ion bombardment comprises using a parallel plate plasma tool to perform said ion bombardment.

7. The method of claim 1, wherein said step of exposing said contacts to ion bombardment comprises using an RIE tool to perform said ion bombardment.

8. A method of improving the resistance of contacts on an integrated circuit, comprising the steps of:
exposing said contacts to ion bombardment in the presence of a fluorine and oxygen plasma, thereby removing inorganic contaminants; and
exposing said contacts to a solvent, thereby removing organic contaminants.

9. The method of claim 8, wherein said step of exposing said contacts to a solvent removes a portion of the contact.

10. The method of claim 8, further comprising the step of oxidizing said pad to produce an oxide layer of a predetermined thickness after said steps of exposing said contacts to ion bombardment and exposing said contacts to a solvent.

11. The method of claim 8, wherein said step of exposing said contacts to a solvent comprises exposing said contacts to a solvent selected from the group consisting of n-methyl pyrrolidone, isopropyl alcohol, methanol, glycol, or a dimethylacetamide-based formulation.

12. The method of claim 8, wherein said step of exposing said contacts to a solvent comprises exposing said contacts to a formulation comprising n-methylethanolamine, dimethylacetamide, 8-hydroxyquinoline, and water.

13. The method of claim 8, wherein said step of exposing said contacts to ion bombardment comprises using an inductively coupled plasma.

14. The method of claim 8, wherein said step of exposing said contacts to ion bombardment comprises using an RF/microwave plasma.

15. A method of forming contacts on an integrated circuit, comprising the steps of:
depositing a protective overcoat over said integrated circuit, including over a plurality of bond pads on said integrated circuit;
removing said protective overcoat from said bond pads in a reactive ion etching process carried out in a reactive ion etching tool;
exposing said bond pads to ion bombardment, wherein said ion bombardment is carried out in said reactive ion etching tool; and
attaching a coupling member to said pad after said step of exposing said pad to ion bombardment.

16. The method of claim 15, wherein following said step of exposing said bond pads to ion bombardment carried out in said reactive ion etching tool, said method further comprises the step of exposing said bond pads to ion bombardment in the presence of a fluorine and oxygen plasma.

17. The method of claim 15, further comprising the step of exposing said bond pads to a solvent.

18. The method of claim 17, wherein said step of exposing said bond pads to a solvent comprises exposing said bond pads to a solvent selected from the group consisting of n-methyl pyrrolidone, isopropyl alcohol, methanol, glycol, or a dimethylacetamide-based formulation.

19. The method of claim 16, wherein said step of exposing said bond pads to ion bombardment in the presence of a fluorine and oxygen plasma comprises using an inductively coupled plasma.

20. The method of claim 16, wherein said step of exposing said bond pads to ion bombardment in the presence of a fluorine and oxygen plasma comprises using an RF/microwave plasma.
